(19) United States
(12) Patent Application Publication
(10) Pub. No.: US 2009/0072390 A1
(43) Pub. Date: Mar. 19, 2009

(54) SEMICONDUCTOR APPARATUS AND FABRICATION METHOD THEREOF

(75) Inventors: Hideo NISHIUCHI, Kawasaki-shi (JP); Tomohiro IGUCHI, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/207,726

(22) Filed: Sep. 10, 2008

(30) Foreign Application Priority Data
Sep. 13, 2007 (JP) 2007-237766

(51) Int. Cl. H01L 23/495; H01L 21/60

(52) U.S. Cl. 257/735; 438/121; 257/E23.032; 257/E21.506

(57) ABSTRACT

A semiconductor apparatus (1) includes a semiconductor device (2), a first lead (3) having an electrode for connection with a source electrode (S) of the semiconductor device (2), a second lead (4) having an electrode for connection with a gate electrode (G) of the semiconductor device (2), a third lead (5) having an electrode for connection with a drain electrode (D) of the semiconductor device (2), and a strap member (6) covered with a metallic film for electrical interconnection between the drain electrode (D) of the semiconductor device (2) and the electrode of the third lead (5).

### CROSS REFERENCE TO RELATED APPLICATIONS

This application is based upon and claims the benefit of priority from prior Japanese Patent Application 2007-237766 filed on Sep. 13, 2007 the entire contents of which are incorporated by reference herein.

### BACKGROUND OF THE INVENTION

1. Field of the Invention

The present invention relates to a semiconductor apparatus having a strap member connected with an electrode of a semiconductor device to thereby reduce an internal resistance, and a fabrication method of the same.

2. Description of the Related Art

Semiconductor markets have recent demands for a semiconductor apparatus adapted for a high-level processing ability and high-speed actions, affording low power consumption when working. In order to overcome such two contrary objects, they push advancing miniaturization of circuitry for semiconductor apparatuses, and reducing an entirety of internal resistances (e.g. on-resistances) of semiconductor apparatus for efficient use of supplied power.

As an example of the semiconductor apparatus, one may take a transistor package including an FET (field effect transistor) employed for a current switching or amplification. In such a transistor package, a semiconductor device has a set of electrodes provided thereon and a set of lead electrodes disposed in correspondence thereto, and the sets of electrodes are interconnected by a plurality of wires made of a conductive metal, such as gold (Au) or aluminum (Al).

Such a semiconductor apparatus has as internal resistances thereof metallic wires employed as current conducting members. Resistances of the metallic wires may amount to a significant proportion of a total internal resistance of the semiconductor apparatus.

As a measure to solve such a problem, Japanese Patent Publication No. 3,240,292 (referred herein to “JP 3,240,292 B”) has disclosed a semiconductor apparatus in which, for an entirety of resistances of the apparatus to be reduced, planer conductive metallic members are used for electrical connections between electrodes of a semiconductor device and electrodes of associated leads. This semiconductor apparatus has increased sectional areas of current conduction paths between the electrodes of semiconductor device and the electrodes of leads, with resultant reduction in resistances between semiconductor device and leads.

FIG. 14 is a plan view of a semiconductor apparatus disclosed in JP 3,240,292 B. The semiconductor apparatus 100 includes: first leads 101; a semiconductor device 102; second leads 103; a third lead 104; a strap member 105 for electrical connection between the semiconductor device 102 and the second leads 103; and a metallic wire 106 for electrical connection between the semiconductor device 102 and the third lead 104. There is a sealing resin member (referred herein to “enclosure”) 107 covering the first leads 101, semiconductor device 102, second leads 103, third lead 104, strap member 105, and metallic wire 106. In FIG. 14, the semiconductor device 102 has regions of source electrodes S and a gate electrode G thereof defined by broken lines respectively.

The first leads 101 have their unshown first lead electrodes. The first leads 101 are electrically connected through a die-bond material to drain electrodes D of the semiconductor device 102. The second leads 103 have their unshown second lead electrodes. The second leads 103 are electrically connected through the strap member 105 to the source electrodes S of the semiconductor device 102. The third lead 104 has an unshown third lead electrode. The third lead 104 is electrically connected through the metallic wire 106 to the gate electrode G of the semiconductor device 102. With a voltage applied through the third lead 104 and the metallic wire 106 to the gate electrode G, electric currents are conducted between the source electrodes S and the drain electrodes D.

### SUMMARY OF THE INVENTION

The arrangement disclosed in JP 3,240,292 B employs the metallic wire 106 for connection between the third lead 104 and the gate electrode G of the semiconductor device 102, and has a limitation to promote reduction of resistances in the semiconductor apparatus.

There are planer metallic members joined by using, e.g., a conductive paste or a high melting point solder. As the high melting point solder, a lead rich solder is used in most cases. Nowadays, for solders to be used in implementation of substrates, the use of lead is regulated. For solders inside a semiconductor apparatus, the use of lead is exempt from the regulation. However, it is desirable to possibly cut back on the use even inside a semiconductor apparatus, taking into consideration the degree of effect of lead on the environment.

As a lead-free solder containing no lead, there is a tin (Sn)-based solder. However, this lead-free solder has a melting point as low as 250° C. or less. Therefore, in implementation of substrates, where the reflow temperature rises up to 260° C., there occurs a remelting of solder inside a semiconductor apparatus in a reflow.

On the other hand, as a lead-free solder having a high melting point, there is a gold-tin (Au—Sn) solder, which is employable for connection in the form of a paste or pellets. In use as pellets, the processing costs high. In use as a paste, the connection requires a post-cleaning, resulting in an increased step number in fabrication of semiconductor apparatus, even in comparison with a semiconductor apparatus employing a wire bonding.

The present invention has been devised in view of the foregoing points. It therefore is an object of the present invention to provide a semiconductor apparatus and a fabrication method thereof allowing for a more reduced internal resistance, high reliability, and facilitated fabrication.

To achieve the object, according to an aspect of the present invention, a semiconductor apparatus comprises a semiconductor device, a first lead having an electrode for connection with a source electrode of the semiconductor device, a second lead having an electrode for connection with a gate electrode of the semiconductor device, a third lead having an electrode for connection with a drain electrode of the semiconductor device, and a strap member covered with a metallic film for electrical interconnection between the drain electrode of the semiconductor device and the electrode of the third lead.

According to another aspect of the present invention, a semiconductor apparatus comprises a semiconductor device, a first lead having an electrode for connection with a source electrode of the semiconductor device, a second lead having an electrode for connection with a gate electrode of the semiconductor device, and a strap member covered with a metallic film configured at an end thereof with a terminal for use in implementation of a substrate and at another end thereof for electrical connection with a drain electrode of the semiconductor device.

According to another aspect of the present invention, a fabrication method of a semiconductor apparatus comprises the steps of applying a die-bond material to a first lead to be connected to a source electrode of a semiconductor device and a second lead to be connected to a gate electrode of the semiconductor device, forming an insulation layer to be brought into contact with the source electrode of the semiconductor device on a third lead to be connected to a drain electrode of the semiconductor device; connecting the semiconductor device onto the first lead, the second lead, and the third lead, having a metallic film covering a strap member for interconnection between the drain electrode of the semiconductor device and the third electrode, and electrically interconnecting the drain electrode of the semiconductor device and an electrode provided to the third electrode by the strap member covered with the metallic film by melting the metallic film by a thermal compression bonding.

According to another aspect of the present invention, a fabrication method of a semiconductor apparatus comprises the steps of applying a die-bond material to a first lead to be connected to a source electrode of a semiconductor device and a second lead to be connected to a gate electrode of the semiconductor device, forming on the second lead an insulation layer to be brought into contact with the source electrode of the semiconductor device, connecting the semiconductor device to the first lead and the second lead, having a metallic film covering a strap member configured at an end thereof with a terminal for use in implementation of a substrate, and electrically connecting another end of the strap member covered with the metallic film to the drain electrode of the semiconductor device by melting the metallic film by a thermal compression bonding.

According to any one of the foregoing aspects of the present invention, a semiconductor apparatus or a fabrication method thereof is adapted to allow for a more reduced internal resistance, high reliability, and facilitated fabrication.

### BRIEF DESCRIPTION OF THE ACCOMPANYING DRAWINGS

FIG. 1 is a perspective view of an entirety of a semiconductor apparatus according to a first embodiment of the present invention.

FIG. 2 is a sectional view along line A-A of FIG. 1 of the semiconductor apparatus according to the first embodiment.

FIG. 3 is a sectional view along line B-B of FIG. 2 of the semiconductor apparatus according to the first embodiment.

FIG. 4 is a sectional view of a work describing a fabrication method of the semiconductor apparatus according to the first embodiment.

FIG. 5 is a sectional view of a work describing the fabrication method of the semiconductor apparatus according to the first embodiment.

FIG. 6 is a sectional view of a work describing the fabrication method of the semiconductor apparatus according to the first embodiment.

FIG. 7 is a sectional view of a work describing the fabrication method of the semiconductor apparatus according to the first embodiment.

FIG. 8 is a perspective view of an entirety of a semiconductor apparatus according to a second embodiment of the present invention.

FIG. 9 is a sectional view along line C-C of FIG. 8 of the semiconductor apparatus according to the second embodiment.

FIG. 10 is a sectional view along line E-E of FIG. 9 of the semiconductor apparatus according to the second embodiment.

FIG. 11 is a sectional view of a work describing a fabrication method of the semiconductor apparatus according to the second embodiment.

FIG. 12 is a sectional view of a work describing the fabrication method of the semiconductor apparatus according to the second embodiment.

FIG. 13 is a sectional view of a work describing the fabrication method of the semiconductor apparatus according to the second embodiment.

FIG. 14 is a plan view of a conventional semiconductor apparatus.

### DETAILED DESCRIPTION OF THE PREFERRED EMBODIMENTS

There will be detailed the preferred embodiments of the present invention, with reference to the accompanying drawings.

### First Embodiment

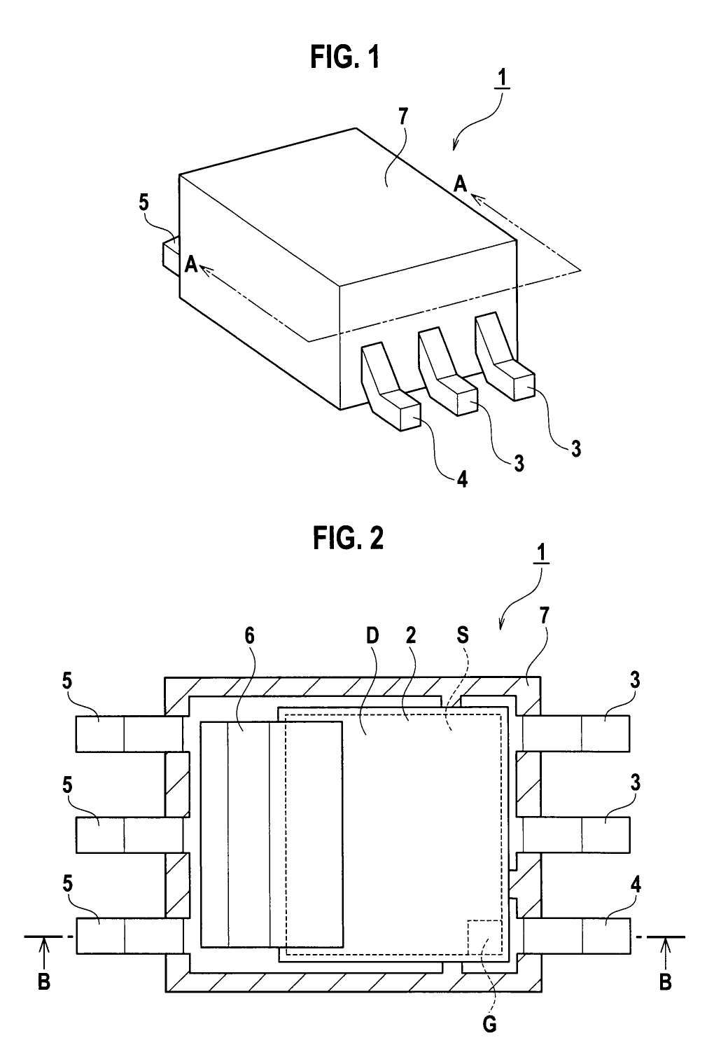

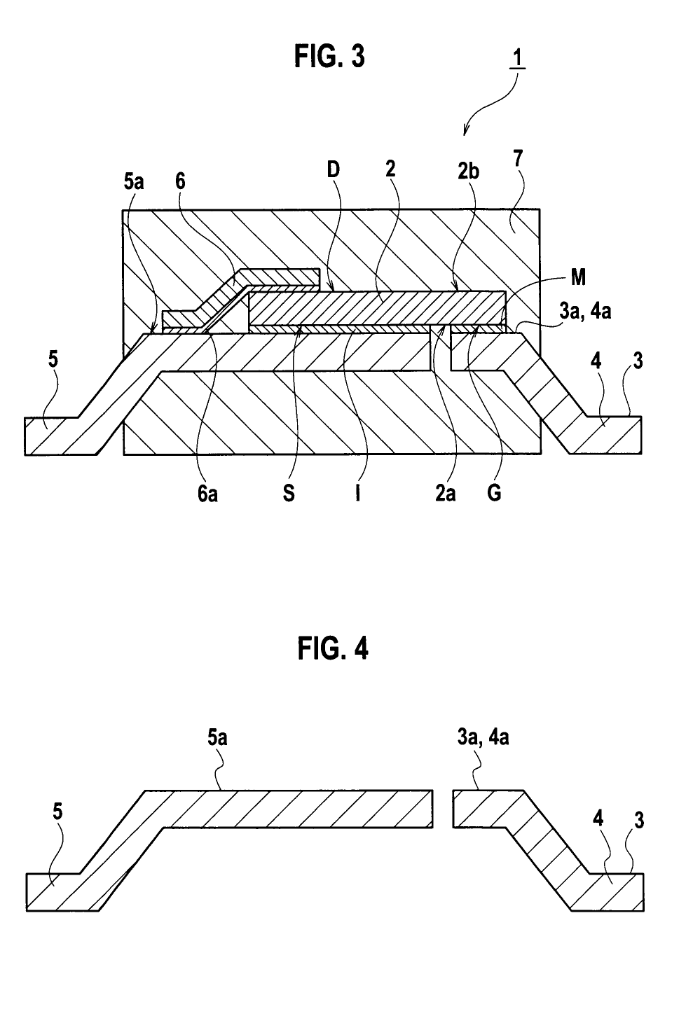

Description is now made of configuration of a semiconductor apparatus according to a first embodiment of the present invention. FIG. 1 shows, in a perspective view, an entirety of the semiconductor apparatus 1. The semiconductor apparatus 1 includes: a semiconductor device 2; a frame of first bent leads (referred herein to “first leads”) 3 having their electrodes to be connected to source electrodes S of the semiconductor device 2; a second bent lead having an electrode to be connected to a gate electrode G of the semiconductor device 2; a frame of third bent leads (referred herein to “third leads”) 5 having their electrodes to be connected to drain electrodes D of the semiconductor device 2; and a strap member 6 covered with metallic films 6a (see FIG. 3) for electrical interconnections between the drain electrodes D of the semiconductor device 2 and the electrodes of the third leads 5. It further includes a sealing resin member (referred herein sometimes to “enclosure”) 7 covering the semiconductor device 2, the first leads 3, the second lead 4, the third leads 5, and the strap member 6.

The enclosure 7 is configured to substantially enclose an entire outside of the semiconductor apparatus 1. In the semiconductor apparatus 1 according to the present embodiment, the first, second, and third leads 3, 4, and 5 are two, one, and three in number, respectively, and six in total, whereas the semiconductor apparatus 1 may have preset arbitrary numbers of leads.

FIG. 2 is a sectional view along line A-A of FIG. 1 of the semiconductor apparatus 1. The first and second leads 3 and 4 and the third leads 5 have their distal ends oppositely exposed outside at both sides of the enclosure 7. The first, second, and third leads 3, 4, and 5 have their proximal ends covered by the enclosure 7. The distal ends of the leads constitute terminals for connection when implemented on a substrate. In the sectional view along line A-A of the semiconductor apparatus 1, the semiconductor device 2 has a region of the drain electrodes D appearing on an obverse side, as defined by solid lines in FIG. 2. It has regions of the source electrodes S and the gate electrode G, which are provided on a reverse side, and defined by broken lines.

FIG. 3 is a sectional view along line B-B of FIG. 2 of the semiconductor apparatus 1. As shown in FIG. 3, the proximal end of the second lead 4 is electrically connected to the gate electrode G of the semiconductor device 2, through a die-bond material M thereon. In the present embodiment, the semiconductor device 2 is connected through the die-bond material M to the second lead 4, at one side 2a thereof provided with the gate electrode G and the source electrodes S, and has the drain electrodes D on the other side (i.e. the obverse side) 2b in opposition to that side 2a.

The one side 2a of the semiconductor device 2 is disposed above the third leads 5. However, that side 2a has the region of source electrodes S, which should be electrically isolated from the third leads 5 to be connected to the drain electrodes D. Hence, over a greater region than the region of source electrodes S, there is formed an insulation layer I contacting on the third leads 5. The semiconductor device 2 is thus arranged on the third leads 5, with the insulation layer I interposed in between.

The first and second leads 3 and 4 and the third leads 5 have their proximal end portions for the die-bond material M and the insulation layer I to be provided on top faces 3a, 4a, and 5a thereof, which are set flush in height so that the semiconductor device 2 put on the first, second, and third leads 3, 4, and 5 will not tilt.

The drain electrodes D provided on the obverse side 2b of the semiconductor device 2 are connected to lead electrodes provided on the third leads 5. In the present embodiment, the drain electrodes D and the third leads 5 are electrically interconnected with each other by the strap member 6 covered with the metallic films 6a. However, the obverse side 2b of the semiconductor device 2 has a step as a difference in level to the top faces 5a of the third leads 5 where the lead electrodes are provided. For electrical interconnections of such electrodes, the strap member 6 is worked out in a bent form to absorb the step.

As illustrated in FIG. 3, the strap member 6 is bent so as to extend straight linearly between the obverse side 2b and the top faces 5a. Instead, the strap member may be bent in an arbitrary form, such as an arc describing form or a crank form between the obverse side 2b and the top faces 5a, subject to an ensured connection with the drain electrodes D on the obverse side 2b.

The strap member 6 is configured for electrical interconnections between the drain electrodes D on the obverse side 2b of the semiconductor device 2 and the lead electrodes on the third leads 5. In the present embodiment, the strap member 6 is made of copper (Cu) in a form, which is covered with the metallic films 6a made of gold and tin (Au—Sn). The metallic films may totally cover the strap member 6. Or else, they may be provided simply on regions to be connected to the electrodes on the top faces 5a and the obverse side 2b, in order to reduce the cost, or for an enhanced sucking property to a tool to be used when putting the strap member 6 on the semiconductor device 2 or the like.

The metallic films 6a made of gold and tin (Au—Sn) may be formed in an arbitrary manner. For instance, they may be a solder plated on the strap member 6, by way of an electrolytic plating or non-electrolytic plating. For the plating, a resist material may be applied, to provide solder skins simply on regions to be plated. Alternatively, an Au—Sn solder paste may be applied, hardened, and washed to thereby provide Au—Sn solder coats on necessary regions.

Such the semiconductor device 2, first leads 3, second lead 4, third leads 5, and strap member 6 are covered by the enclosure 7 to provide the semiconductor apparatus 1.

Description is now made of a fabrication method of the semiconductor apparatus 1 according to the first embodiment, with reference to FIG. 4 to FIG. 7. These figures illustrate sections of works corresponding to FIG. 3, where the first leads 3 are superposed behind the second lead 4.

First, as illustrated in FIG. 4, a combination of a set of first leads 3 and a second lead 4 and a set of third leads 5, as they are worked out in bent forms with inclined parts, are arranged in opposite positions, where top faces 3a and 4a of the first and second leads 3 and 4 and top faces 5a of the third leads 5 are set at a level, to be flush with each other, constituting a single imaginary plane.

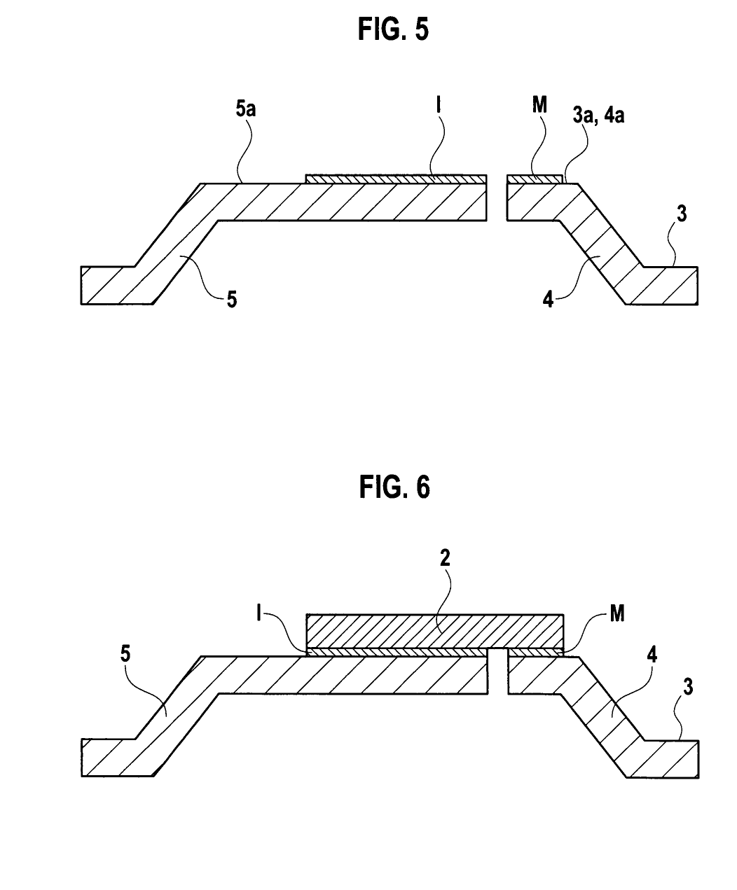

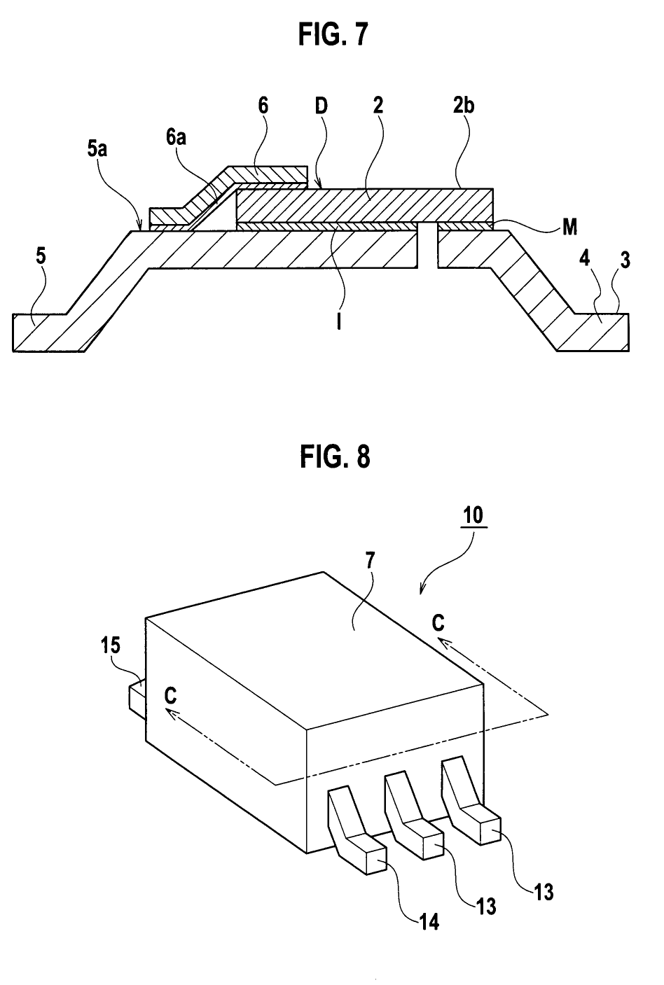

Next, as illustrated in FIG. 5, coats of a die-bond material M are put on top faces 3a and 4a of the first and second leads 3 and 4, and an insulation layer I is formed on top faces 5a of the third leads 5. The die-bond material M to be used may well be a composite of, among others, gold and germanium (Au—Ge) or gold and silicon (Au—Si), having a higher melting point than metallic films (Au—Sn) to be formed on a strap member 6 (see FIG. 7).

The insulation layer I may be formed in an arbitrary manner, e.g., by a method of having insulation sheets mounted on the top faces 5a and cured, or a method of coating polyimide on the top faces 5a.

Next, as illustrated in FIG. 6, a semiconductor device 2 is placed on the coats of die-bond material M and the insulation layer I, to make necessary connections, that is, to connect source electrodes S of the semiconductor device 2 to the first leads 3, and a gate electrode G of the semiconductor device 2 onto the second lead 4. The semiconductor device 2 has a region placed on the insulation layer I on the top faces 5a of third leads 5, where no connection is made to the first leads 3 nor the second lead 4.

A separate process has prepared a strap member 6 covered with metallic films 6a made of an alloy of gold and tin (Au—Sn).

Next, as illustrated in FIG. 7, drain electrodes D on the obverse side 2b of the semiconductor device 2 and lead electrodes on top faces 5a of the third leads 5 are electrically interconnected with each other by the strap member 6. More specifically, using an unshown tool, the strap member 6 is sucked up, transferred, and placed in position on the drain electrodes D and the lead electrodes. Then, the tool is operated to exert pressures on an upside of the strap member 6, so this is forced onto the drain electrodes D and the lead electrodes, and connected thereto. The strap member 6 is thereby shaped in a form bridging a region of the drain electrodes D and an imaginary single plane the top faces 5a constitute.

Such connection of the strap member 6 will not be favorable if the obverse side 2a or any top face 5a is oxidized. The metallic films 6a of gold and tin (Au—Sn) on the strap member 6 need to melt to serve as a connection material. Hence, the third leads 5 (as well as the first and second leads 3 and 4) are put on a stage of e.g. 320° C., for a heating in a reducing atmosphere where the semiconductor device 2 and the third leads 5 are interconnected by the strap member 6. The strap member is thus connected by a thermal compression bonding to the obverse side 2b and the top faces 5a.

After that, the semiconductor device 2, the first leads 3, the second lead 4, the third leads 5, and the strap member 6 are covered by the enclosure 7. For the molding, there may be employed a transfer molding, potting molding, or the like. The enclosure 7 may be of any kind, providing that the property is suitable for the semiconductor device. By such a flow of fabrication steps, the semiconductor apparatus 1 shown in FIG. 1 is obtainable.

Such being the case, in a semiconductor apparatus according to the present embodiment, a gate electrode G and source electrodes S of a semiconductor device 2 are directly connected to leads, respectively, thereby eliminating the use of a metallic wire having been required for interconnection between a gate electrode G and a lead, thus reducing the number of sets of interconnections between a semiconductor device and leads, from two being a combination of a gate electrode G and a set of source electrodes S, to one being a set of drain electrodes D. Therefore, assuming the size of a semiconductor device to be same as ever, the size of an entirety of a semiconductor apparatus may well be reduced, with a contribution to down-sizing the semiconductor apparatus. On the contrary, assuming the size of a semiconductor apparatus to be same as ever, the size of a semiconductor device may well be enlarged, with a contribution to performance enhancement of the semiconductor device.

For structural reason, a semiconductor device has a whole set of drain electrodes D on a drain electrode side, and a combination of a set of source electrodes S and a gate electrode G on an opposite side. According to the present embodiment, a strap member is employed for interconnections between drain electrodes D and associated lead electrodes. Therefore, in configuration for interconnection between drain electrodes D and lead electrodes, the position for interconnection by a strap member can be set in a voluntary manner, as an advantage.

According to the present embodiment, a semiconductor apparatus employs a strap member formed with metallic films of gold and tin (Au—Sn), and the metallic films melt in a thermal compression bonding, allowing for electrical interconnections by the strap member between electrodes of a semiconductor device and electrodes of third leads.

This eliminates following a conventional flow of fabrication steps including applying a material for connection on a semiconductor device and leads, placing a strap member, and entering a reflow followed by a cleaning. It can do simply by using a gold and tin (Au—Sn) plated strap member and making connections by a thermal compression bonding, thus allowing for a lump sum execution of conventional fabrication steps, with a possible reduction of fabrication time.

Gold and tin (Au—Sn) alloy metallic films formed on a strap member 6 melt in a thermal compression bonding, thereby connecting the strap member 6 with a semiconductor device and leads. This permits the use of a lead-free connection material. The metallic films have a melting point about 280° C., which is higher than a reflow temperature (260° C.) in implementation of semiconductor apparatus on a substrate, and prevents occurrences of remelt in the reflow, thus allowing for stable connections of the strap member 6 with the semiconductor device and the leads.

It can be avoided to use a paste of gold and tin (Au—Sn) solder for connections of a strap member with a semiconductor device and leads. This affords, even when heated for connection, to be free of, among others, flux, solvent or such exuding from a paste containing it, or production of voids, thus allowing for an eliminated cleaning step, and avoidable adverse effects such as faulty connections due to void production or increase in power consumption.

It therefore is possible to provide a semiconductor apparatus and a fabrication method thereof allowing for the more reduced internal resistance, with secured high reliability, and facilitated fabrication.

### Second Embodiment

Description is now made of a second embodiment of the present invention, with reference to FIG. 8 to FIG. 10. Relative to the first embodiment, like elements or members are designated by like reference characters to eliminate redundancy.

In the semiconductor apparatus 1 according to the first embodiment, electrodes of the semiconductor device 2 and the third leads 5 are electrically interconnected with each other by the strap member 6. In the second embodiment, a strap member is configured to concurrently work as a set of third leads.

As illustrated in FIG. 8, in a semiconductor apparatus 10 according to the second embodiment, parts of a strap member 15 (not the third leads 5 in the first embodiment) are extended outside an enclosure 7, for use as terminals in implementation on a substrate. There is provided a combination of a frame of first leads 13 to be connected to source electrodes S, and a second lead 14 to be connected to a gate electrode G, while also the first and second leads 13 and 14 are different in shape from the first and second leads 3 and 4 in the first embodiment.

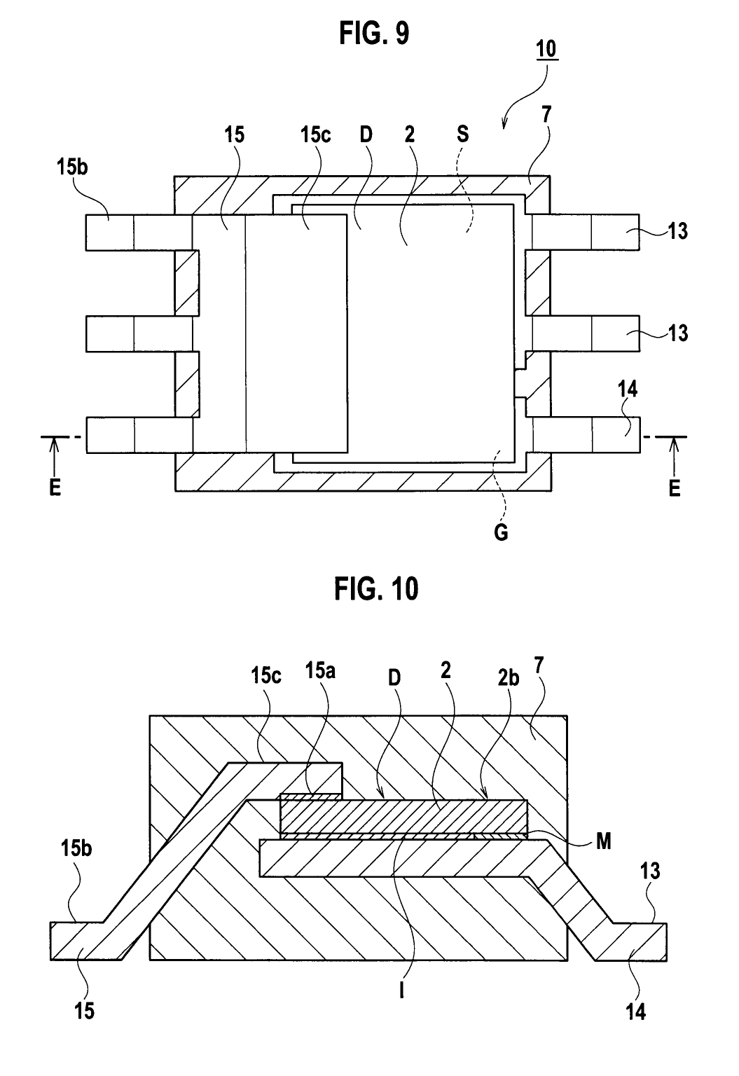

FIG. 9 is a sectional view along line C-C of FIG. 8 of the semiconductor apparatus 10. As illustrated in FIG. 9, the semiconductor apparatus 10 has a semiconductor device 2 placed on and connected to the first and second leads 13 and 14. The first and second leads 13 and 14 and the strap member 15 have their distal ends (as their parts constituting connection terminals when implemented on a substrate, and specifically designated as “terminals” 15b for the strap member 15) oppositely exposed outside at both sides of the enclosure 7. The first and second leads 13 and 14 and the strap member 15 have their proximal ends covered by the enclosure 7.

FIG. 10 is a sectional view along line E-E of FIG. 9 of the semiconductor apparatus 10. As illustrated in FIG. 10, the source and gate electrodes S and G of the semiconductor device 2 are connected, through coats of a die-bond material M and electrically directly (i.e., without using metallic wires), to proximal end portions of the first and second leads 13 and 14, respectively. The die-bond material M may be applied on whole top faces of proximal end portions of the first leads 13 to be connected to the source electrodes S. An insulation layer I is formed for electrical isolation between a region of source electrodes S of the semiconductor device 2 and a corresponding region of a top face of proximal end portion of the second lead 14.

The strap member 15 is configured at its distal ends as the terminals 15b, and at its proximal end portion as a terminal portion 15c for electrical connection with drain electrodes D on an obverse side 2b of the semiconductor device 2. As illustrated in FIG. 10, the semiconductor device 2 is placed on the first and second leads 13 and 14, constituting a step between the terminals 15b and the terminal portion 15c of the strap member 15. The strap member 15 is worked out in a bent form to absorb the step. As illustrated in FIG. 10, the strap member 15 is bent so as to extend straight linearly between the terminals 15b and the terminal portion 15c. Instead, the strap member may be bent in an arbitrary form, such as a crank form, or an arc describing form avoiding interferences of the terminal portion 15c with an edge of the obverse side 2b between the terminals 15b and the terminal portion 15c, subject to an ensured connection with the drain electrodes D on the obverse side 2b.

In the present embodiment, the strap member 15 is made of copper (Cu) in a form, which is covered with metallic films 15a made of gold and tin (Au—Sn). The metallic films 15a formed on the strap member 15 serve as a connection material in connection with electrodes on the obverse side 2b. Hence, in the second embodiment, they are formed simply on regions to be connected with drain electrodes D on the obverse side 2b.

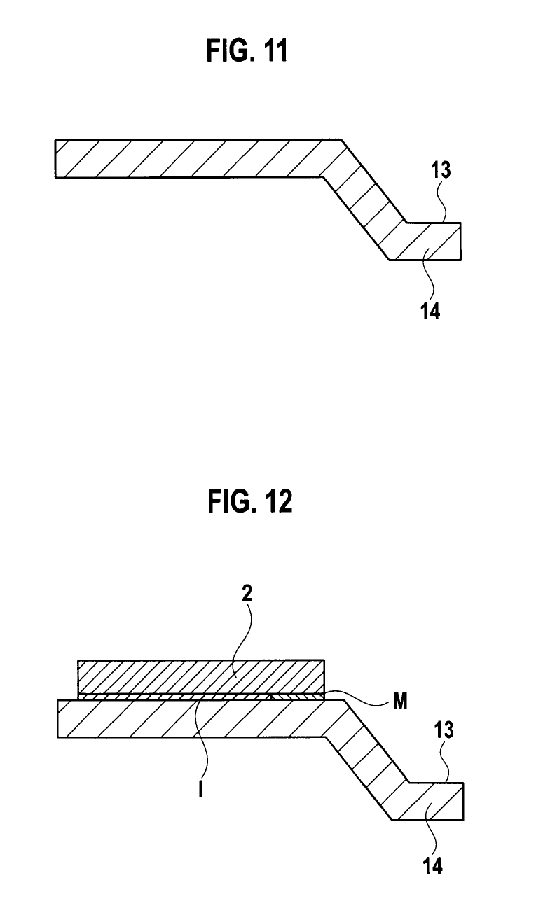

Description is now made of a fabrication method of the semiconductor apparatus 10 according to the second embodiment, with reference to FIG. 11 to FIG. 13. These figures illustrate sections of works corresponding to FIG. 10, where the first leads 13 are superposed behind the second lead 14.

First, as illustrated in FIG. 11, a set of first leads 13 and a second lead 14 are arranged in prescribed positions, where top faces of proximal end portions of the first and second leads 13 and 14 are set at an adequate level in accordance with a size of the semiconductor apparatus 10. Next, as illustrated in FIG. 12, coats of a die-bond material M are provided on the top faces of proximal end portions of the first leads 13 and a corresponding region of the top face of proximal end portion of the second lead 14, and an insulation layer I is formed on the remaining region of the top face of proximal end portion of the second lead 14, and then, the semiconductor device 2 is mounted on them, and connected through the coats of die-bond material M with the first and second leads 13 and 14. In a separate process, there is prepared a strap member 15 formed with metallic films 15a made of an alloy of gold and tin (Au—Sn).

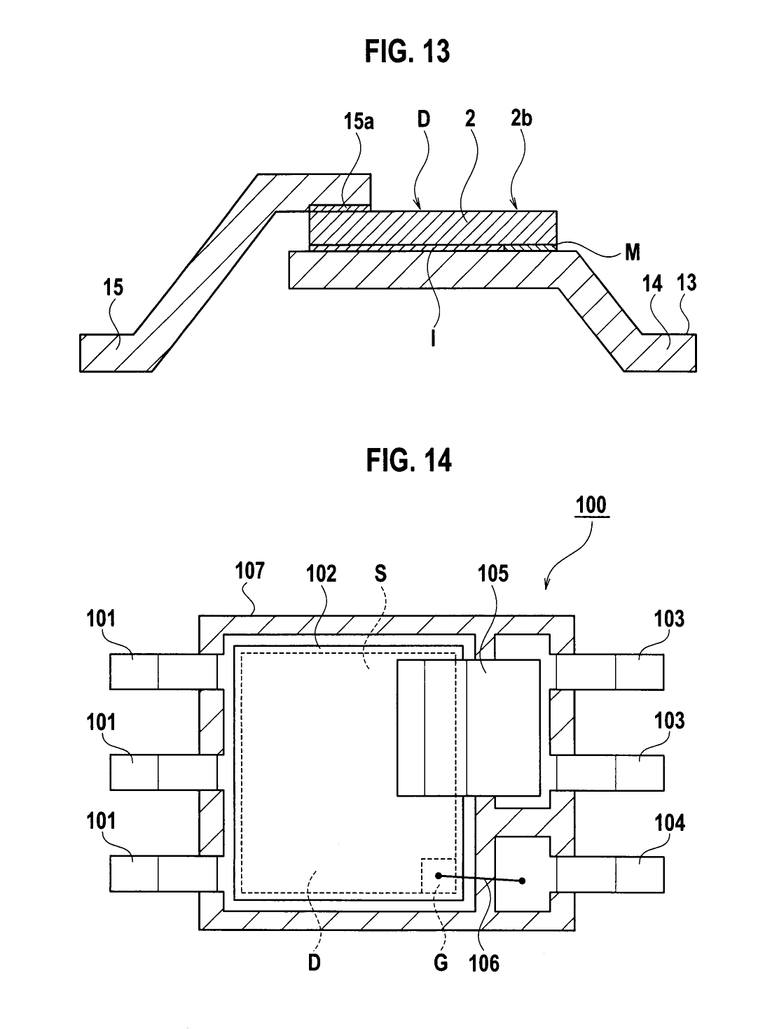

Next, as illustrated in FIG. 13, the strap member 15 is connected to drain electrodes D on the obverse side 2b of the semiconductor device 2. More specifically, using an unshown tool, the strap member 15 is sucked up, transferred, and placed in position on a region (of drain electrodes D) for connection with the obverse side 2b. Then, the tool is operated to exert pressures on an upside of the strap member 15, so this is forced onto the obverse side 2b, and connected therewith.

For this connection, in a reducing atmosphere, the second lead 14 (as well as the first leads 13) is put on a stage of e.g. 320° C. for a heating to effect a thermal compression bonding. In the thermal compression bonding, gold and tin (Au—Sn) alloy metallic films 15a formed on the strap member 15 melt, effecting the connection with electrodes o the obverse side 2b. By such a flow of fabrication steps, the semiconductor apparatus 10 shown in FIG. 8 is obtainable.

Such being the case, in a semiconductor apparatus according to the present embodiment, a gate electrode G and source electrodes S of a semiconductor device 2 are directly connected to leads, respectively, thereby eliminating the use of a metallic wire having been required for interconnection between a gate electrode G and a lead, thus reducing the number of sets of interconnections between a semiconductor device and leads, from two being a combination of a gate electrode G and a set of source electrodes S, to one being a set of drain electrodes D. Therefore, assuming the size of a semiconductor device to be same as ever, the size of an entirety of a semiconductor apparatus may well be reduced, with a contribution to down-sizing the semiconductor apparatus. On the contrary, assuming the size of a semiconductor apparatus to be same as ever, the size of a semiconductor device may well be enlarged, with a contribution to performance enhancement of the semiconductor device. Further, there is employed a strap member formed with metallic films of gold and tin (Au—Sn), and the metallic films melt in a thermal compression bonding, allowing for electrical connections of the strap member with electrodes of a semiconductor device. It therefore is possible to provide a semiconductor apparatus and a fabrication method thereof allowing for the more reduced internal resistance, with secured high reliability, and facilitated fabrication.

That is, in addition to the effects of the first embodiment described, no need of the third leads afford to reduce the number of components of the semiconductor apparatus, allowing for provision of a semiconductor apparatus and a fabrication method thereof with the more enhanced reliability, facilitated fabrication, and reduced internal resistance.

It is noted that the present invention is not restricted to the foregoing embodiments as they are, and may be implemented with changes to their components without departing from the scope of appended claims. Further, those components disclosed in the foregoing embodiments may be adequately combined. For example, some components of an embodiment may be eliminated, or components of embodiments may be combined.

While preferred embodiments of the present invention have been described using specific terms, such description is for illustrative purposes, and it is to be understood that changes and variations may be made without departing from the spirit or scope of the following claims.

What is claimed is:

1. A semiconductor apparatus comprising:
a semiconductor device;
a first lead having an electrode for connection with a source electrode of the semiconductor device;
a second lead having an electrode for connection with a gate electrode of the semiconductor device;
a third lead having an electrode for connection with a drain electrode of the semiconductor device; and
a strap member covered with a metallic film for electrical interconnection between the drain electrode of the semiconductor device and the electrode of the third lead.

2. A semiconductor apparatus comprising:
a semiconductor device;
a first lead having an electrode for connection with a source electrode of the semiconductor device;
a second lead having an electrode for connection with a gate electrode of the semiconductor device; and
a strap member covered with a metallic film configured at an end thereof with a terminal for use in implementation of a substrate and at another end thereof for electrical connection with a drain electrode of the semiconductor device.

3. The semiconductor apparatus according to claim 1, wherein the metallic film covering the strap member comprises an alloy of gold and tin.

4. The semiconductor apparatus according to claim 2, wherein the metallic film covering the strap member comprises an alloy of gold and tin.

5. A fabrication method of a semiconductor apparatus comprising the steps of:
applying a die-bond material to a first lead to be connected to a source electrode of a semiconductor device and a second lead to be connected to a gate electrode of the semiconductor device;
forming an insulation layer to be brought into contact with the source electrode of the semiconductor device on a third lead to be connected to a drain electrode of the semiconductor device;
connecting the semiconductor device onto the first lead, the second lead, and the third lead;
having a metallic film covering a strap member for interconnection between the drain electrode of the semiconductor device and the third electrode; and
electrically interconnecting the drain electrode of the semiconductor device and an electrode provided to the third electrode by the strap member covered with the metallic film by melting the metallic film by a thermal compression bonding.

6. A fabrication method of a semiconductor apparatus comprising the steps of:
applying a die-bond material to a first lead to be connected to a source electrode of a semiconductor device and a second lead to be connected to a gate electrode of the semiconductor device;
forming on the second lead an insulation layer to be brought into contact with the source electrode of the semiconductor device;
connecting the semiconductor device to the first lead and the second lead;
having a metallic film covering a strap member configured at an end thereof with a terminal for use in implementation of a substrate; and
electrically connecting another end of the strap member covered with the metallic film to the drain electrode of the semiconductor device by melting the metallic film by a thermal compression bonding.
